(19) United States
(12) Patent Application Publication
(10) Pub. No.: US 2008/0310128 A1
(43) Pub. Date: Dec. 18, 2008

(54) Variable Height Plug-In Pads and Equalizers

(76) Inventor: Robert M. Blumenkranz, Brea, CA (US)

Correspondence Address: SoCAL IP LAW GROUP LLP, 310 N. WESTLAKE BLVD. STE 120, WESTLAKE VILLAGE, CA, 91362, US

(21) Appl. No.: 11/763,626

(22) Filed: Jun. 15, 2007

(51) Int. Cl. H05K 1/00

(52) U.S. Cl. 361/748

(57) ABSTRACT

The electronic component mounts the circuitry and connector pins at the bottom of a substrate. The upper portion of the substrate has one or more weakened horizontal lines allowing the user to break off part of the upper portion of the substrate. Doing so allows a technician to shorten the component so that it properly fits into a cable system amplifier. A cap with indicia or color-coding may fit over the top of the substrate to help handling the component and identifying its type and electrical values.

### BACKGROUND

1. Field

Plug-in pads and equalizers primarily used with coaxial cable transmission systems.

2. General Background and State of the Art

Coaxial cable transmission systems distribute and transmit cable television and broadband communications signals such high speed Internet, VoIP, and other signals. Over the long distances of these systems, resistive and dielectric losses cause signal attenuation.

Typical cable transmission systems use amplifiers spaced throughout the coaxial cable network to compensate for attenuation and slope loss. These amplifiers have electrical components, pads and equalizers for adjusting the amplifiers' output. Typically, technicians change the pads and equalizers in amplifiers to modify the system parameters.

Pads and equalizers may have different heights. However, they plug into standard three-pin sockets. Typically, they extend through openings in the amplifier cover into the socket. Depending on the size of the amplifier, a long pad or equalizer may project above the cover opening improperly. On the other hand, a technician installing a very short pad or equalizer may be unable to reach the socket with the component.

### INVENTION SUMMARY

The electronic component includes electrical contacts mounted on a substrate at the bottom of the substrate. The upper portion of the substrate has one or more weakened horizontal lines allowing the user to break off part of the upper portion of the substrate. Doing so shortens the component so that it properly fits into a cable system amplifier without projecting above the top cover. In addition, by starting with a taller electronic component, all will extend near the cover and none will be too short.

A cap may be provided that fits over the top of the substrate. The cap may have indicia or be color coded for showing the electrical values and type of electronic component.

### BRIEF DESCRIPTION OF THE DRAWINGS

FIG. 1 is a front view of an exemplary embodiment of the electronic component described in this application.

FIG. 2 is a front view of the exemplary embodiment of FIG. 1 with part of the component removed.

FIG. 3 is a front view of another exemplary embodiment of the electronic component described in this application.

### DETAILED DESCRIPTION OF THE PREFERRED EMBODIMENTS

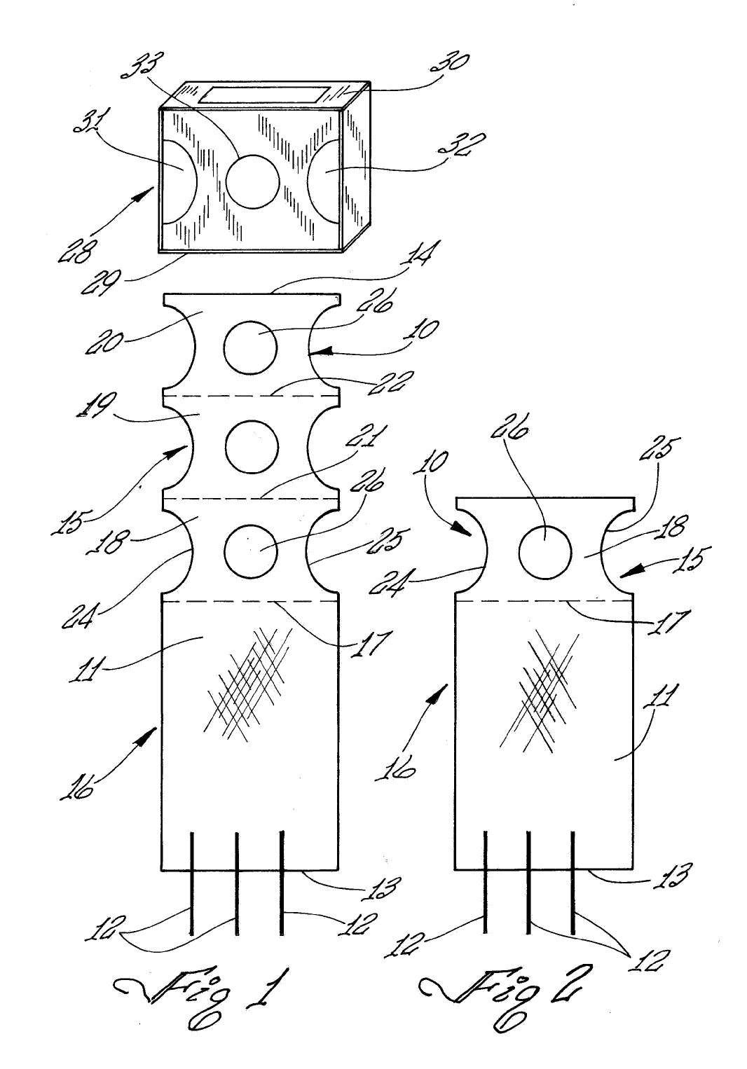

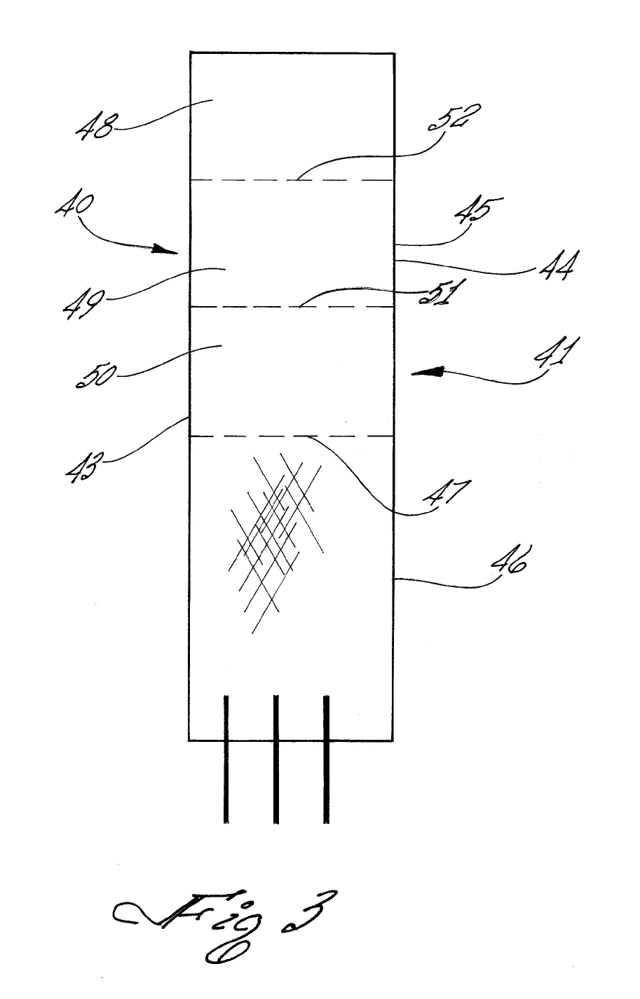

Electronic components such as pads and equalizers for cable television systems come in different heights. Component 10 in FIG. 1 is an exemplary component. Component 10 is formed on a substrate 11. The exemplary embodiment uses printed circuit board FR4 material 0.063 in. (1.6 mm) thick. The electronic circuitry (not shown) typically mounts on one side of the substrate, but it could mount on both sides. The substrate is divided into two portions, an upper portion 15 and a lower portion 16. Line 17 (FIGS. 1 and 2) divides the two portions. Pins 12 electrically connect to the circuitry. FIGS. 1 and 2 show the pins extending below the substrate's bottom edge 13, but the pins may be along the bottom edge or be elsewhere. The top edge 14 of the substrate is parallel to the bottom end in the exemplary embodiment.

Upper portion 15 is subdivided into three subdivisions 18, 19 and 20 (FIG. 1). Though the exemplary embodiment has three subdivisions, other embodiments could have fewer or more subdivisions. Moreover, one could design the upper portion to have no subdivisions.

In the FIG. 1 exemplary embodiment, each subdivision has scalloped sides, e.g., sides 24 and 25 of subdivision 18. The subdivisions also have a center hole 26. The scalloped sides and holes make gripping the component easier. However, the scalloped sides, the hole or both can be eliminated. Compare straight sides 43 and 44 in FIG. 3. In addition, instead of the scalloped sides, other embodiments could have surfaces, coatings or other means for assisting with gripping.

Lines 17, 21 and 22 are weakened portions of the substrate formed by scoring or etching the substrate. Thus, when a technician bends the substrate above and below a line, the portion above the line will break off from the remainder of the substrate. For example, if the technician holds subdivision 18 in one hand and the rest of the component in the other hand near line 21 and bends the two parts of the substrate about line 21, subdivisions 19 and 20 will break off. Consequently, the component becomes shorter. See FIG. 2.

Depending on the desired height of the component, the technician uses the component as follows: (a) as is; (b) with subdivision 20 removed; (c) with two subdivisions 19 and 20 removed; or (d) with all the subdivisions 18, 19 and 20 removed. Thus, in FIG. 2, the technician has removed subdivisions 19 and 20 to make component 10 shorter.

Though the exemplary embodiments contemplate a technician breaking one or more subdivisions in the field, he or she could do so before going into the field. Breaking off subdivisions also could occur in an automated process.

An optional cap 28 (FIG. 1) mounts over the upper edge 14 of component 10. That is, the bottom 29 of cap 28 has a slot (not shown) sized to receive the upper edge 14 of the substrate. By constructing cap 28 of somewhat resilient material or sizing the slot properly, the cap stays on the substrate unless the technician purposely removes the cap.

The cap allows the technician a convenient grip for component 10. Caps used with the present invention also could be color-coded based on features of the component. For example, caps for pads would be one color or one group of colors, and caps used with equalizers would be another color or another group of colors. One also could use designs (plaid, hatching, symbols, etc.) in lieu of colors.

The top surface 30 of the cap may have a surface on which the component's value (e.g., 3 dB) is printed or written. The color or design scheme also could reflect values. By aligning the various components that a technician carries with the top surfaces of the caps facing upward, the technician relying on color, other indicia and printed values can find the proper component quickly. Likewise, the color and indicia allow technicians to determine quickly what components are in an amplifier.

Cap 28 has optional scallops 31 and 32 and an optional hole 33 to mesh with the scallops and holes in the FIG. 1 exemplary embodiment. Special or roughened surfaces, coatings or other means could be provided to help grip the cap.

Component 40 in the FIG. 3 exemplary embodiment is similar to the FIG. 1 embodiment. Substrate 41 is divided into two portions, upper portion 45 and lower portion 46. Scored or etched line 47 (FIG. 3) divides the two portions. Three subdivisions 48, 49 and 50 subdivide upper portion 45.

In the FIG. 3 exemplary embodiment, upper portion 45 has straight sides 43 and 44. Etched or scored lines 47, 51 and 52 are weakened portions of the substrate and allow technicians to break off one or more subdivision at one of the lines. The FIG. 3 exemplary embodiment lacks an optional cap although one could be used.

The foregoing are merely illustrative and not limiting, having been presented by way of example only. Although examples have been shown and described, it will be apparent to those having ordinary skill in the art that changes, modifications or alterations may be made.

Although many of the examples presented involve specific combinations of method acts or system elements, those acts and elements may be combined in other ways to accomplish the same objectives. Acts, elements and features discussed only in connection with one embodiment are not intended to be excluded from a similar role in other embodiments.

For means-plus-function limitations recited in the claims, the means are not intended to be limited to the means disclosed herein for performing the recited function but are intended to cover in scope any means, known now or later developed, for performing the recited function.

“Plurality” means two or more. A “set” of items may include one or more of such items. As used in this application, whether in the written description or the claims, the terms “comprising,” “including,” “carrying,” “having,” “containing,” “involving,” and the like are to be understood to be open-ended, i.e., to mean “including but not limited to.” Only the transitional phrases “consisting of” and “consisting essentially of,” respectively, are closed or semi-closed transitional phrases with respect to claims.

Use of ordinal terms such as “first,” “second,” “third,” etc., in the claims to modify a claim element does not by itself connote any priority, precedence, or order of one claim element over another or the temporal order in which acts of a method are performed. The terms are used merely as labels to distinguish one claim element having a certain name from another element having a same name (but for use of the ordinal term) to distinguish the claim elements.

I claim:

1. An electronic component comprising:
a) an elongated substrate having top and bottom ends;
b) an electrical connector at the bottom end attachable to an electrical receptacle; and
c) at least one weakened portion on the substrate above the electrical connector.

2. The electronic component of claim 1 wherein top and bottom ends are straight-sided and parallel to each other, the at least one weakened portion being in the form of a narrow line parallel to the top and bottom ends.

3. The electronic component of claim 1 further comprising a cap, the top end of the substrate being insertable into the cap.

4. The electronic component of claim 3 wherein the cap has means for indicating the properties of the component.

5. The electronic component of claim 1 wherein the substrate has material removed from portions of the substrate above the bottom end.

6. A method for changing electrical values of an amplifier, wherein the amplifier has a socket for receiving an electrical component mounted on a substrate, the method comprising: determining whether the electrical component fits into amplifier properly, breaking off a portion of the substrate to cause the electrical component to fit into the amplifier.

7. An electronic component comprising a substrate having an upper portion and a lower portion, the lower portion having a bottom edge and an electrical connector at the bottom edge, the upper portion having a top edge, the upper portion having at least one weakened portion capable of being broken off and removed from the remainder of the substrate.

8. The electronic component of claim 7 wherein top and bottom ends are straight-sided and parallel to each other, the at least one weakened portion being in the form of a narrow line parallel to the top and bottom ends.

9. The electronic component of claim 7 further comprising a cap, the top end of the substrate being insertable into the cap.

10. The electronic component of claim 9 wherein the cap has means for indicating the properties of the component.
